(19) United States
(12) Patent Application Publication
(10) Pub. No.: US 2012/0235228 A1
(43) Pub. Date: Sep. 20, 2012

(54) TRANSISTOR STRUCTURE AND METHOD FOR PREPARING THE SAME

(75) Inventors: Chin Ling Huang, Taoyuan City (TW); Tieh Chiang Wu, Dayuan Township (TW)

(73) Assignee: NANYA TECHNOLOGY CORP., Kueishan (TW)

(21) Appl. No.: 13/049,053

(22) Filed: Mar. 16, 2011

(51) Int. Cl. H01L 29/78; H01L 21/336

(52) U.S. Cl. 257/330; 438/270; 257/E29.255; 257/E21.409

(57) ABSTRACT

A buried channel transistor structure includes a semiconductor substrate; a conductive block positioned in the semiconductor substrate; a gate dielectric layer positioned between the conductive block and the semiconductor substrate; and a bulge-shaped dielectric structure positioned on the conductive block and the gate dielectric layer.

### 1. TECHNICAL FIELD

The present invention relates to a transistor structure and method for preparing the same, and more particularly, to a buried channel transistor structure and a method for preparing the same.

### 2. BACKGROUND

As semiconductor fabrication technology continues to improve, sizes of electronic devices are reduced, and the size and the channel length of the conventional planar channel transistor also decrease correspondingly. The planar channel transistor has been widely used in the integrated circuit; however, the continuous decreasing of the size and the channel length of the planar channel transistor results in a serious interaction between the two doped regions and a carrier channel under the gate oxide layer such that the controlling ability of the conductive metal layer on the switching operation of the carrier channel is reduced, i.e., causes the so-called short channel effect, which impedes the functioning of the planar channel transistor. To address this problem, researchers developed the so-called buried channel transistor with a buried gate sandwiched between the two doped regions and an increased channel length.

FIG. 1 to FIG. 3 illustrate a method for preparing a buried channel transistor 10 according to the prior art. First, a pad oxide layer 15 is formed to cover a semiconductor substrate 11 with a trench isolation structure 13, and an etching mask 17 having a plurality of openings 19 is then formed on the pad oxide layer 15. Subsequently, a dry etching process is performed to remove a portion of the semiconductor substrate 11 under the openings 19 of the etching mask 17 so as to form a plurality of recesses 21 in the semiconductor substrate 11, as shown in FIG. 2.

Referring to FIG. 3, after removing the etching mask 17, a dielectric layer 25, a buried gate 23, and a dielectric layer 27 filling the recesses 21 are formed. Subsequently, an implanting process is performed to implant dopants into the semiconductor substrate 11 and form two doped regions 29 serving as the source and the drain at two sides of the buried gates 23 in the semiconductor substrate 11.

FIG. 4 is a close-up cross-sectional view of the buried channel transistor 10 according to the prior art. The buried gates 23 includes a top end 23A and a bottom end 23B, and the separation space between the top end 23A and the doped region 29 in the semiconductor substrate 11 is the same as the separation space between the bottom end 23B and the semiconductor substrate 11, i.e., the separation space is the thickness of the dielectric layer 25. In particular, there is an angle corner 31 at the top end 23A of the buried gates 23, and the angle corner 31 generates high electrical field. Consequently, the buried channel transistor 10 exhibits a significant gate induced drain leakage (GIDL) current. In addition, the high electrical field also influences the reliability and performance of the dielectric layer 25.

### SUMMARY

One aspect of the present invention provides a buried channel transistor structure and a method for preparing the same.

In one embodiment of the present invention, a buried channel transistor structure comprises a semiconductor substrate; a conductive block positioned in the semiconductor substrate; a gate dielectric layer positioned between the conductive block and the semiconductor substrate; and a bulge-shaped dielectric structure positioned on the conductive block and the gate dielectric layer.

In one embodiment of the present invention, a method for preparing a buried channel transistor structure comprises the steps of forming at least one recess in a semiconductor substrate; forming a first dielectric layer in the recess; forming a conductive block in a bottom portion of the recess; forming a liner mask covering an upper portion of the first dielectric layer in the recess; removing a portion of the first dielectric layer and the semiconductor substrate not covered by the liner mask to form a bulge-shaped depression in the semiconductor substrate; and forming a bulge-shaped dielectric structure filling the depression.

The foregoing has outlined rather broadly the features of the present invention in order that the detailed description of the invention that follows may be better understood. Additional features of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives of the present invention will become apparent upon reading the following description and upon reference to the accompanying drawings in which:

FIG. 1 to FIG. 3 illustrate a method for preparing a buried channel transistor 10 according to the prior art;

FIG. 4 is a close-up cross-sectional view of the buried channel transistor according to the prior art;

FIG. 5 is a cross-sectional view showing the formation of at least one recess according to one embodiment of the present invention;

FIG. 6 is a cross-sectional view showing the filling of the recess by conductive material according to one embodiment of the present invention;

FIG. 7 is a cross-sectional view showing the formation of a conductive block and liner mask according to one embodiment of the present invention;

FIG. 8 is a cross-sectional view showing the formation of a bugle-shaped depression according to one embodiment of the present invention;

FIG. 9 is a cross-sectional view showing the formation of a mask layer according to one embodiment of the present invention;

FIG. 10 is a cross-sectional view showing a transistor structure according to one embodiment of the present invention; and

FIG. 11 is a close-up cross-sectional view of the transistor structure according to one embodiment of the present invention;

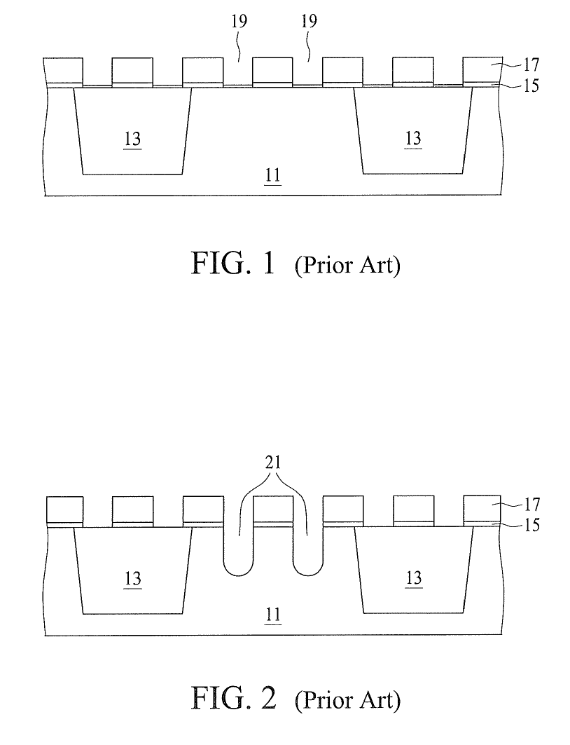

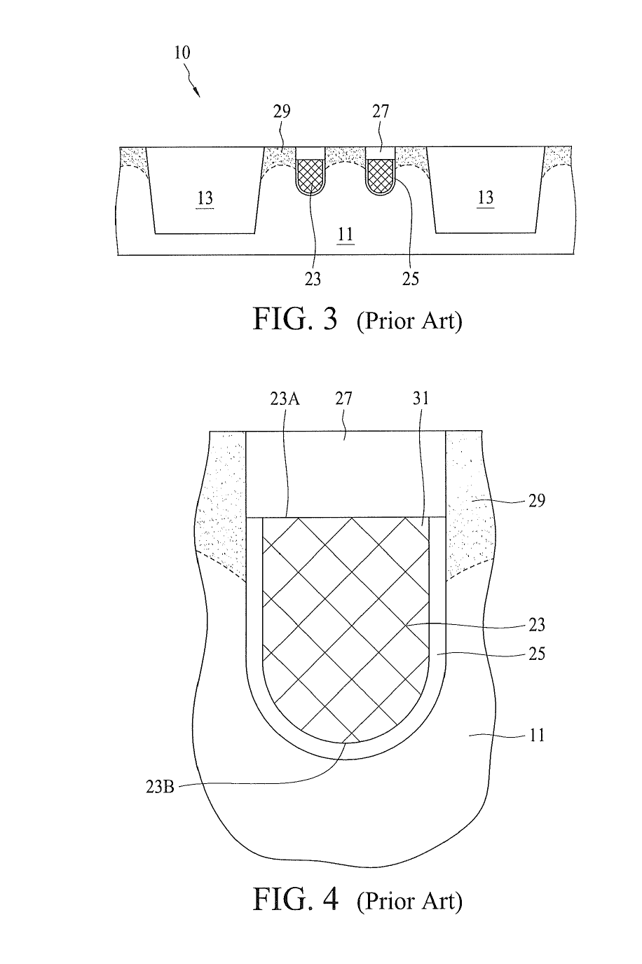

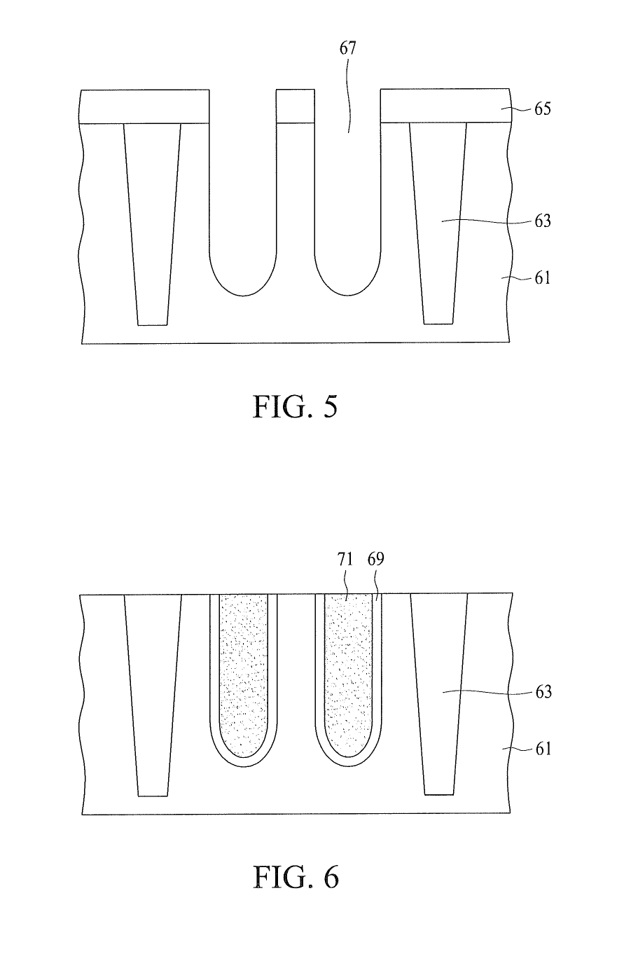

### DETAILED DESCRIPTION

FIG. 5 to FIG. 11 are cross-sectional views showing the formation of a transistor structure 60 according to one embodiment of the present invention. FIG. 5 is a cross-sectional view showing the formation of at least one recess 67 according to one embodiment of the present invention. In one embodiment of the present invention, a patterned mask layer 65 is formed on a semiconductor substrate 61 such as the silicon substrate with a shallow trench isolation 63, and an etching process such as the dry etching process is performed to remove a portion of the semiconductor substrate 61 not covered by the patterned mask layer 65 to form at least one recess 67 in the semiconductor substrate 61.

FIG. 6 is a cross-sectional view showing the filling of the recess 67 by conductive material 71 according to one embodiment of the present invention. In one embodiment of the present invention, a thermal oxidation process is performed to form a first dielectric layer 69 such as the silicon oxide layer on the surface of the recess 67, and a deposition process is then performed to fill the recess 67 with conductive material 71 such as metal.

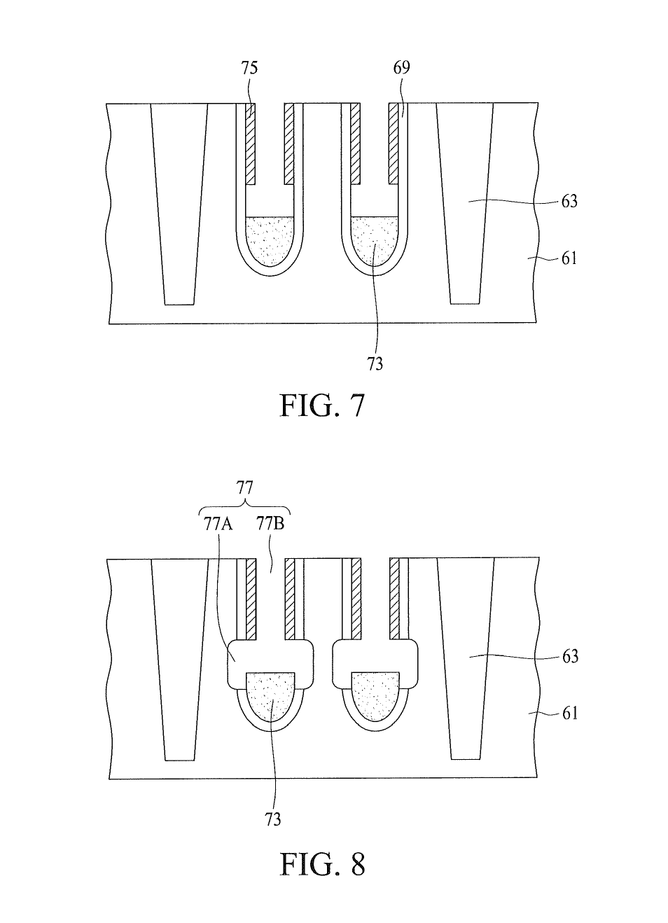

FIG. 7 is a cross-sectional view showing the formation of a conductive block 73 and a liner mask 75 according to one embodiment of the present invention. In one embodiment of the present invention, an etching process such as the dry etching process is performed to remove a portion of the conductive material 71 from an upper portion of the recess 67 to form the conductive block 73 at the bottom portion of the recess 67; subsequently, a liner mask 75 such as a dielectric layer or a metal oxide layer is then formed on the upper portion of the recess 67. In one embodiment of the present invention, the formation of the liner mask 75 comprises the steps of forming a liner layer on the first dielectric layer 69 by a suitable deposition process, and the liner layer is then partially removed by an anisotropic etching process, leaving an upper portion of the liner layer on the side surface of the first dielectric layer 69, thereby forming the vertically oriented liner mask 75. In one embodiment of the present invention, the liner mask 75 can be formed directly by performing a deposition process, with controlling the reaction pressure of the deposition process to control the liner depth below the surface of the semiconductor substrate 61.

FIG. 8 is a cross-sectional view showing the formation of a bugle-shaped depression 77 according to one embodiment of the present invention. In one embodiment of the present invention, an etching process such as the wet etching process is performed by using the liner mask as the etching mask to remove a portion of the first dielectric layer 69 and the semiconductor substrate 61 not covered by the liner mask 75 to form a bulge-shaped depression 77 in the semiconductor substrate 61, wherein the bulge-shaped depression 77 includes a wide portion 77A on the conductive block 73 and a narrow portion 77B on the wide portion 77A.

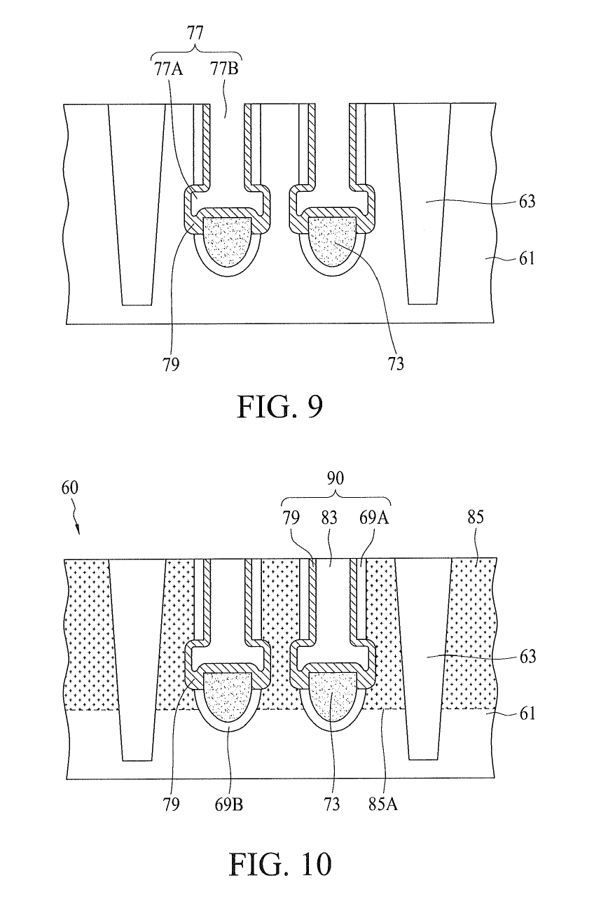

FIG. 9 is a cross-sectional view showing the formation of a mask layer 79 according to one embodiment of the present invention. In one embodiment of the present invention, the liner mask 75 is stripped, and a deposition process is then performed to form the mask layer 79 covering the conductive block 73 and the sidewall surface of the wide portion 77A of the bulge-shaped depression 77, without filling up the bulge-shaped depression 77. Subsequently, in one embodiment of the present invention, a thermal treating process such as the rapid thermal oxidation (RTO) is performed to cause oxidation reaction at a predetermined portion of the mask layer 79 proximate to the semiconductor substrate 61. The original mask layer 79 is formed by the deposition process and may possess defects to cause leakage. The thermal treating process is performed to improve the quality of a predetermined portion of the mask layer 79 proximate to the semiconductor substrate 61, i.e., to repair the defect in the mask layer 79; wherein the mask layer 79, covering the conductive block 73, serves to prevent the metal of the conductive block 73 from being oxidized.

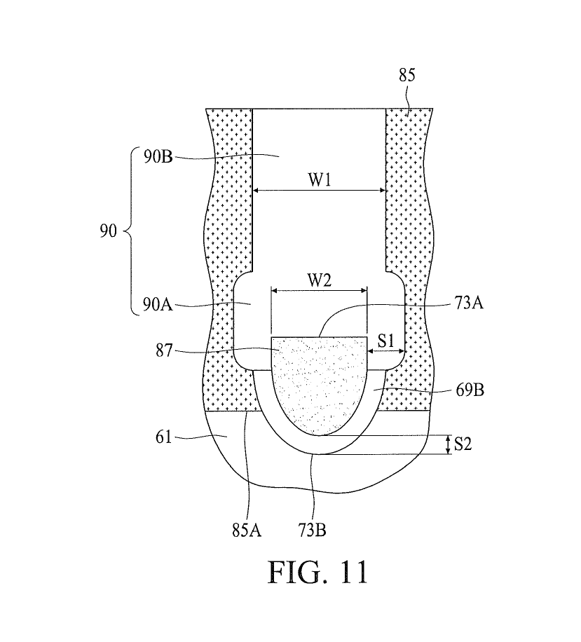

FIG. 10 is a cross-sectional view showing the transistor structure 60 according to one embodiment of the present invention, and FIG. 11 is a close-up cross-sectional view of the transistor structure 60 according to one embodiment of the present invention. In one embodiment of the present invention, a dielectric layer 83 is formed on the conductive block 73, and an implanting process is then performed to form at least one doped region 85 at the side of the conductive block 73 in the semiconductor substrate 61 to complete the transistor structure 60. In particular, the top portion 69A of the dielectric layer 69, the mask layer 79, and the dielectric layer 83 form a bulge-shaped dielectric structure 90. In one embodiment of the present invention, the conductive block 73 serves as the gate, the bottom portion 69B of the dielectric layer 69 serves as the gate dielectric layer, and the doped region 85 serves as the source/drain of the transistor structure 60.

Referring to FIG. 11, in one embodiment of the present invention, the bulge-shaped dielectric structure 90 includes a wide portion 90A positioned on the conductive block 73 and a narrow portion 90B positioned on the wide portion 90A. In one embodiment of the present invention, the width W1 of the narrow portion 90B is larger than the width W2 of the conductive block 73. In one embodiment of the present invention, the conductive block 73 includes a top end 73A and a bottom end 73B, and the top end 73A is separated from the semiconductor substrate 61 by the bulge-shaped dielectric structure 90. In one embodiment of the present invention, the doped region 85 includes a bottom end 85A below the top end 73A of the conductive block 73. In one embodiment of the present invention, the bottom end 85A of the doped region 85 is below the bulge-shaped dielectric structure 90.

In one embodiment of the present invention, the top end 73A of the conductive block 73 includes an angle corner 87, and the wide portion 90A of the bulge-shaped dielectric layer 90 covers the angle corner 87. In one embodiment of the present invention, the separation space S1 (the width of the wide portion 90A) between the top end 73A and the doped region 85 in the semiconductor substrate 61 is larger than the separation space S2 (the thickness of the gate dielectric layer 69B) between the bottom end 73B and the semiconductor substrate 61. Consequently, the electrical field between the doped region 85 and the angle corner 87 is reduced by the increased the separation space S1 (the width of the wide portion 90A), such that problems of significant gate induced drain leakage (GIDL) current and the reliability of the gate dielectric layer 69B from the high electrical field is effectively solved.

Although the present invention and its objectives have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A transistor structure, comprising:
a semiconductor substrate;
a conductive block positioned in the semiconductor substrate;
a gate dielectric layer positioned between the conductive block and the semiconductor substrate; and
a bulge-shaped dielectric structure positioned on the conductive block and the gate dielectric layer.

2. The transistor structure of claim 1, wherein the conductive block includes a top end with an angle corner, and the bulge-shaped dielectric structure includes a wide portion covering the angle corner.

3. The transistor structure of claim 1, wherein the bulge-shaped dielectric structure includes a wide portion positioned on the conductive block and a narrow portion positioned on the wide portion.

4. The transistor structure of claim 3, wherein the width of the narrow portion is larger than the width of the conductive block.

5. The transistor structure of claim 1, wherein the conductive block includes a top end and a bottom end, the separation space between the top end and the semiconductor substrate is larger than the separation space between the bottom end and the semiconductor substrate.

6. The transistor structure of claim 1, wherein the conductive block includes a top end separated from the semiconductor substrate by the bulge-shaped dielectric structure.

7. The transistor structure of claim 1, further comprising at least one doped region positioned at the side of the conductive block in the semiconductor substrate.

8. The transistor structure of claim 7, wherein the doped region includes a bottom end below the bulge-shaped dielectric structure.

9. The transistor structure of claim 7, wherein the conductive block includes a top end, and the doped region includes a bottom end below the top end of the conductive block.

10. A method for preparing a transistor structure, comprising the steps of:
forming at least one recess in a semiconductor substrate;
forming a first dielectric layer in the recess;
forming a conductive block in a bottom portion of the recess;
forming a liner mask covering an upper portion of the first dielectric layer in the recess;
removing a portion of the first dielectric layer and the semiconductor substrate not covered by the liner mask to form a bulge-shaped depression in the semiconductor substrate; and
forming a bulge-shaped dielectric structure filling the depression.

11. The method for preparing a transistor structure of claim 10, wherein the forming of the first dielectric layer in the recess is performing a thermal oxidation process.

12. The method for preparing a transistor structure of claim 10, wherein the forming of the conductive block comprises the steps of:
filling the recess with conductive material; and
performing an etching process to remove a portion of the conductive material from an upper portion of the recess.

13. The method for preparing a transistor structure of claim 10, wherein the forming of the bulge-shaped depression in the semiconductor substrate is performing a wet etching process by using the liner mask as an etching mask.

14. The method for preparing a transistor structure of claim 10, further comprising a step of removing the liner mask from the recess.

15. The method for preparing a transistor structure of claim 14, further comprising steps of:
forming a mask layer covering the conductive block; and
performing a thermal treating process to convert a portion of the mask layer proximate to the semiconductor substrate.

16. The method for preparing a transistor structure of claim 10, further comprising a step of forming at least one doped region at the side of to the conductive block in the semiconductor substrate.

17. The method for preparing a transistor structure of claim 16, wherein the conductive block includes a top end, and the doped region includes a bottom end below the top end of the conductive block.
